(19) United States
(12) Patent Application Publication
(10) Pub. No.: US 2024/0069081 A1
(43) Pub. Date: Feb. 29, 2024

(54) SIGNAL ANALYSIS FOR COMPUTING A COMPLEMENTARY CUMULATIVE DISTRIBUTION FUNCTION

(71) Applicant: Keysight Technologies, Inc., Santa Rosa, CA (US)

(72) Inventor: Rishi Mohindra, Milpitas, CA (US)

(21) Appl. No.: 17/900,449

(22) Filed: Aug. 31, 2022

(51) Int. Cl. G01R 23/167; G01R 23/18

(52) U.S. Cl. CPC G01R 23/167; G01R 23/18

(57) ABSTRACT

A signal analysis system includes a memory and a processor. The memory stores instructions; and the processor executes the instructions. When executed by the processor, the instructions cause the signal analysis system to: filter an orthogonal frequency-division multiplexed signal with a first filtering bandwidth larger than a modulation bandwidth of the orthogonal frequency-division multiplexed signal to produce a filtered analog signal; digitize the filtered analog signal to obtain a digitization of the filtered analog signal; obtain a single measurement of a modulated waveform from the digitization; upsample the single measurement at a multiple of five (5) times or higher of a Nyquist sampling rate; and compute a complementary cumulative distribution function (CCDF) of the modulated waveform of the orthogonal frequency-division multiplexed signal based on upsampling the single measurement.

### BACKGROUND

The probability density function (PDF) of a continuous function is the probability that the variable of the continuous function has the value x, and this is often expressed in terms of an integral between two points, i.e., point a and point b. For a continuous distribution, the cumulative distribution function (CDF) is the probability that the variable takes a value less than or equal to x, and this may be expressed also in terms of an integral between negative infinity and x. A complementary cumulative distribution function (CCDF) for time-domain data of a measured signal shows the amount of time the measured signal power is above a given power level x in a measurement interval, and thus the probability that the signal power will be above the power level x. The value of x is typically normalized to the average power level, and therefore measured in dB. The CCDF curve is plotted versus decibels (dB) on the X axis and as a percent on the Y axis. CCDF is plotted by network analyzers that measure signals such as orthogonal frequency division multiplexed (OFDM) signals when testing equipment.

As uses have developed for signals at increasingly higher frequencies, network analyzers are typically set to the lowest possible sampling rates when sampling OFDM signals at the higher frequencies. Some network analyzers may measure the CCDF of a 5G NR (5G New Radio) modulated waveform or wireless local area network (WLAN) modulated waveform using the lowest possible sampling rate of approximately 1.25 times the modulation bandwidth. This sampling rate significantly undersamples the modulated waveforms at the higher frequencies, and this results in an inability to consistently capture peaks of OFDM signals. Measuring a single undersampled waveform misses many of the peaks of the OFDM signals during the sampling process by the analog-to-digital (A/D) converter and therefore misreports the CCDF curve at the higher signal levels.

Increasing the sampling rate of OFDM signals corresponds to a wider bandwidth, and this results in flooding more noise into the data of the measured signal. As a result, the CCDF of the measured signal sampled at an increased sampling rate is shifted to Gaussian noise, making the CCDF curve untrustworthy for any particular undersampled waveform at higher frequencies. To circumvent this, repeated measurements of the waveform may be taken and averaged, with the intent of sufficiently randomizing the sampling phase of each measurement of the waveform so as to cover the peak regions of OFDM signals. For short packets of 802.11be signals with 320 Megahertz (MHz) modulation bandwidths, averaging up to 500 repetitions may be needed to make the CCDF reproducible with a constant trace over the averaging. Measured CCDF may vary 2 dB or more at the high peak-to-average power ratio (PAPR) region for a 1.25× Nyquist sampling rate, which is 400 MHz sampling rate for a 320 MHz wide 802.11be signal. Still, peak regions are not consistently measured due to few samples at the low probability region corresponding to the high PAPR region. Accordingly, CCDF curves produced for waveforms of measured signals at high frequencies vary significantly depending on the sampling phase. Even with repeated measurements of waveforms, a network analyzer may be unable to reproduce the CCDF accurately, and such repeated measurements of waveforms are not feasible for high-speed testing, making the use of repeated measurements of waveforms at high frequencies to produce the CCDF impractical.

### SUMMARY

According to an aspect of the present disclosure, A signal analysis system includes a memory and a processor. The memory stores instructions; and the processor executes the instructions. When executed by the processor, the instructions cause the signal analysis system to: filter an orthogonal frequency-division multiplexed signal with a first filtering bandwidth larger than a modulation bandwidth of the orthogonal frequency-division multiplexed signal to produce a filtered analog signal; digitize the filtered analog signal to obtain a digitization of the filtered analog signal; obtain a single measurement of a modulated waveform from the digitization; upsample the single measurement at a multiple of five (5) times or higher of a Nyquist sampling rate; and compute a complementary cumulative distribution function (CCDF) of the modulated waveform of the orthogonal frequency-division multiplexed signal based on upsampling the single measurement.

According to another aspect of the present disclosure, a tangible non-transitory computer readable storage medium stores a computer program. When executed by a processor, the computer program causes a system to: filter an orthogonal frequency-division multiplexed signal with a first filtering bandwidth larger than a modulation bandwidth of the orthogonal frequency-division multiplexed signal to produce a filtered analog signal; digitize the filtered analog signal to obtain a digitization of the filtered analog signal; obtain a single measurement of a modulated waveform from the digitization; upsample the single measurement at a multiple of five (5) times or higher of a Nyquist sampling rate; and compute a complementary cumulative distribution function (CCDF) of the modulated waveform of the orthogonal frequency-division multiplexed signal based on upsampling the single measurement.

According to another aspect of the present disclosure, a method includes filtering an orthogonal frequency-division multiplexed signal with a first filtering bandwidth larger than a modulation bandwidth of the orthogonal frequency-division multiplexed signal to produce a filtered analog signal; digitizing the filtered analog signal to obtain a digitization of the filtered analog signal; obtaining a single measurement of a modulated waveform from the digitization; upsampling the single measurement at a multiple of five (5) times or higher of a Nyquist sampling rate; and computing a complementary cumulative distribution function (CCDF) of the modulated waveform of the orthogonal frequency-division multiplexed signal based on upsampling the single measurement.

According to another aspect of the present disclosure, a method includes filtering an orthogonal frequency-division multiplexed signal having a first filtering bandwidth larger than a modulation bandwidth of the orthogonal frequency-division multiplexed signal to produce a filtered analog signal; digitizing the filtered analog signal to obtain a digitization of the filtered analog signal; obtaining a single measurement of a modulated waveform from the digitization; upsampling the single measurement at a multiple of five (5) times or higher of a Nyquist sampling rate; optionally digitally filter the signal to additionally limit the close-in out-of-band noise either before or after the upsampling; and computing a complementary cumulative distribution function (CCDF) of the modulated waveform of the orthogonal frequency-division multiplexed signal based on upsampling the single measurement.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 illustrates a system for signal analysis for computing a complementary cumulative distribution function, in accordance with a representative embodiment.

FIG. 2 illustrates a user interface of a spectrum analyzer showing signal measurements of a signal with a center frequency of 6 GHz in signal analysis for computing a complementary cumulative distribution function, in accordance with a representative embodiment.

FIG. 3 illustrates a user interface showing varied results for a 400 MHz sampling rate without upsampling and consistent results for the 400 MHz sampling rate with 8 times upsampling, in accordance with a representative embodiment.

FIG. 4 illustrates a user interface showing variations of peak-to-average power ratio with sampling rate, over sampling delay, in accordance with a representative embodiment.

FIG. 5 illustrates a user interface showing effects of upsampling, in accordance with a representative embodiment.

FIG. 6 illustrates a method for signal analysis for computing a complementary cumulative distribution function, in accordance with a representative embodiment.

FIG. 7 illustrates another method for signal analysis for computing a complementary cumulative distribution function, in accordance with a representative embodiment.

### DETAILED DESCRIPTION

In the following detailed description, for the purposes of explanation and not limitation, representative embodiments disclosing specific details are set forth in order to provide a thorough understanding of embodiments according to the present teachings. However, other embodiments consistent with the present disclosure that depart from specific details disclosed herein remain within the scope of the appended claims. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. Definitions and explanations for terms herein are in addition to the technical and scientific meanings of the terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the inventive concept.

As used in the specification and appended claims, the singular forms of terms ‘a’, ‘an’ and ‘the’ are intended to include both singular and plural forms, unless the context clearly dictates otherwise. Additionally, the terms “comprises”, and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to”, “coupled to”, or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

The present disclosure, through one or more of its various aspects, embodiments and/or specific features or sub-components, is thus intended to bring out one or more of the advantages as specifically noted below.

As described herein, a CCDF of an undersampled waveform may be accurately measured using a single measurement by upsampling the signal by a multiple such as 5 times or 10 times. Upsampling is defined as increasing the sampling rate of a signal. The upsampling described herein avoids taking averages of hundreds of measurements, and therefor reduces test time significantly while also improving accuracy of CCDF measurements. As a result, accuracy of network analyzers when measuring CCDC may be improved. The upsampling effectively increases the sample size to capture samples which otherwise have very low probability of being captured.

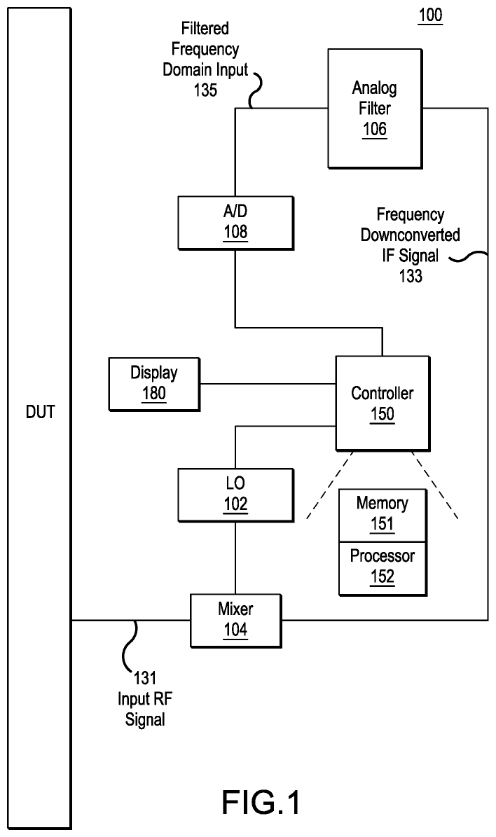

FIG. 1 illustrates a system for signal analysis for computing a complementary cumulative distribution function, in accordance with a representative embodiment.

In FIG. 1, the system 100 is representative of a network analyzer. The DUT 199 in FIG. 1 is representative of a communications device that emits OFDM signals in a time domain channel, such as a cellular telephone. The system 100 is used to measure the OFDM signals from the DUT.

The system 100 includes a local oscillator 102, a mixer 104, an analog filter 106, an A/D 108 (analog-to-digital converter), a controller 150 and a display 180. The controller 150 includes at least a memory 151 that stores instructions and a processor 152 that executes the instructions. The input OFDM signal 131 represents the OFDM signals received from the DUT in the time domain channel. The input OFDM signal 131 is received as a modulated waveform.

The local oscillator 102 is controlled by the controller 150 to downconvert the input OFDM signal 131 via the mixer 104. The frequency downconverted intermediate radio frequency signal 133 is output from the mixer 104 and subject to analog filtering by the analog filter 106, so as to result in the filtered analog input 135. The OFDM signal is filtered by the analog filter 106 with a first filtering bandwidth larger than modulation bandwidth of the OFDM signal to produce the filtered analog input. The filtered analog input 135 is digitized by the A/D 108 to obtain a digitization of the filtered analog signal, and the digitized signal is provided to the controller 150 for analysis to result in a display of the complementary cumulative distribution function (CCDF) described herein. The filtering by the analog filter 106 may be with a first filtering bandwidth larger than a modulation bandwidth of the OFDM signal, and results in a filtered analog signal. The filtering by the analog filter 106 may be with a bandwidth slightly larger than the modulation bandwidth in order to reject the out of band noise and prevent aliasing at the input of the A/D 108.

As an example, a network analyzer may have a 512 MHz bandwidth and a I and Q sampling rate of 1.25 times, so slightly higher. The “real” sampling rate is 2.5 times, so 2.5 multiplied by 512 MHz, which equals 1.28 GHz at the intermediate frequency signal. The real sampling rate is the sum of the I and Q sampling rate, i.e., the complex sampling rate which is 1.25 multiplied by 512 MHz, or 640 MHz. The 512 MHz wide intermediate frequency path may be used for the 320 MHz modulation bandwidth of the 802.11be signal. Accordingly, the analog filter 106 has a first filtering bandwidth slightly wider than 512 MHz in this example, and is placed before the A/D 108 as an anti-aliasing filter to ensure that far-off out-of-band noise does not fold into the passband of the A/D filter 108.

The controller 150 includes at least the memory 151 that stores instructions and the processor 152 that executes the instructions. The controller 150 may also include interfaces, such as a first interface, a second interface, a third interface, and a fourth interface. One or more of the interfaces may include ports, disk drives, wireless antennas, or other types of receiver circuitry that connect the controller 150 to other electronic elements. One or more of the interfaces may include user interfaces such as buttons, keys, a mouse, a microphone, a speaker, a display separate from the display 180, or other elements that users can use to interact with the controller 150 such as to enter instructions and receive output. The controller 150 may perform some of the operations described herein directly and may implement other operations described herein indirectly. For example, the controller 150 may indirectly control operations such as by generating and transmitting content to be displayed on the display 180. The controller 150 may directly control other operations such as logical operations performed by the processor 152 executing instructions from the memory 151 based on input received from electronic elements and/or users via the interfaces. Accordingly, the processes implemented by the controller 150 when the processor 152 executes instructions from the memory 151 may include steps not directly performed by the controller 150.

Either the controller 150 or a separate component such as an application-specific integrated circuit performs digital filtering. After digitization by the A/D 108 at a sampling rate larger than 2 times the analog filter bandwidth to meet Nyquist criterion of the noise bandwidth, narrower digital filtering is performed with a bandwidth slightly larger than the modulation bandwidth to remove out-of-band noise from influencing the CCDF. The controller 150 or the separate component may be configured to filter the digitization with a second filtering bandwidth larger than the modulation bandwidth and smaller than the first filtering bandwidth. The filtering by the controller 150 or the separate component is performed before upsampling the single measurement at the multiple of five (5) times or higher of the Nyquist sampling rate. One or more of the interfaces provided by the system 100 may be configured to accept a selection of the multiple used to upsample the single measurement from a plurality of multiples. For example, the display 180 may display a set of potential multiples and a mouse or keyboard may be configured to accept a selection of the multiple used to upsample the single measurement from the plurality of multiples.

The display 180 may be includes as a component of a network analyzer or as a separate component in the system 100. The display 180 may be connected to the controller 150 via a local wired interface such as an Ethernet cable or via a local wireless interface such as a Wi-Fi connection. The display 180 may be a monitor such as a computer monitor, an electronic whiteboard, or another screen configured to display electronic imagery.

The controller 150 is configured to obtain a single measurement of a modulated waveform from the digitization of the filtered analog input 135, and upsample the single measurement at a multiple of five (5) times or higher of a Nyquist sampling rate to compute the CCDF of the modulated waveform of the OFDM signal based on upsampling the single measurement. The system 100 may upsample the modulated waveform of the OFDM signal so that a single measurement may be used to accurately capture the CCDF of an OFDM signal. The upsampling effectively increases the sample size to capture samples which otherwise have very low probability of being captured. The single measurement may be taken to mean a single measurement of a continuous OFDM signal input as the input OFDM signal 131, as distinguishable from multiple measurements of discontinuous OFDM signal or repeated measurements of the same OFDM signal with random starting phase of the ADC clock relative to the clock of the signal source DAC.

The upsampling by the controller 150 may be by an integer factor so that the net sampling rate is greater than or equal 5 times Nyquist sampling rate, such as 10 times the Nyquist sampling rate. The upsampling may be implemented using, for example, a sinc interpolator. A sinc function represents a symmetric damped sine waveform of length N samples for each discrete sample of the OFDM signal sampled by the system 100, and a sinc interpolator sums the waveforms from N overlapping samples to generate an interpolated waveform without adding higher harmonics.

As an example, upsampling may be performed using zero-insertion followed by using a raised cosine filter with an appropriate bandwidth and impulse length. As particular examples, when the undersampled rate is 1.25 times the Nyquist rate (400 MHz sampling rate for a 320 MHz wide 802.11be signal), upsampling may be by 4 times to obtain 5 times the Nyquist rate, or upsampling may be by 8 times to obtain 10 times the Nyquist rate. The upsampled signal upsampled 5 times to 10 times the Nyquist rate may result in fine sampling over peak regions and will have a CCDF waveform with improved reliability in terms of accuracy.

In the various representative embodiments described herein, a controller (e.g., controller 150) and a memory (e.g., memory 151) are described for signal analysis for computing a complementary cumulative distribution function to carry out the various aspects of the present teachings.

The memory (e.g., memory 151) may include a main memory and/or a static memory, where such memories may communicate with each other and a controller via one or more buses. The memory stores instructions used to implement some or all aspects of methods and processes described herein. The memory may be implemented by any number, type and combination of random access memory (RAM) and read-only memory (ROM), for example, and may store various types of information, such as software algorithms, which serve as instructions, which when executed by a processor cause the processor to perform various steps and methods according to the present teachings. Furthermore, updates to the methods and processes described herein may also be stored in memory.

The various types of ROM and RAM may include any number, type and combination of computer readable storage media, such as a disk drive, flash memory, an electrically programmable read-only memory (EPROM), an electrically erasable and programmable read only memory (EEPROM), registers, a hard disk, a removable disk, tape, compact disk read only memory (CD-ROM), digital versatile disk (DVD), floppy disk, Blu-ray disk, a universal serial bus (USB) drive, or any other form of storage medium known in the art. The memory 151 is a tangible storage medium for storing data and executable software instructions, and is non-transitory during the time software instructions are stored therein. As used herein, the term “non-transitory” is to be interpreted not as an eternal characteristic of a state, but as a characteristic of a state that will last for a period. The term “non-transitory” specifically disavows fleeting characteristics such as characteristics of a carrier wave or signal or other forms that exist only transitorily in any place at any time. The memory 151 may store software instructions and/or computer readable code (collectively referred to as ‘instructions’) that enable performance of various functions of the system 100. The memory 151 may be secure and/or encrypted, or unsecure and/or unencrypted.

“Memory” is an example of computer-readable storage media, and should be interpreted as possibly being multiple memories. The memory for instance may be multiple memories or databases local to the system 100, and/or distributed amongst multiple computer systems or computing devices, or disposed in the ‘cloud’ according to known components and methods. A computer readable storage medium is defined to be any medium that constitutes patentable subject matter under 35 U.S.C. § 101 and excludes any medium that does not constitute patentable subject matter under 35 U.S.C. § 101. Examples of such media include non-transitory media such as computer memory devices that store information in a format that is readable by a computer or data processing system. More specific examples of non-transitory media include computer disks and non-volatile memories.

The controller 150 described below is representative of one or more processing devices, and is configured to execute software instructions stored in memory to perform functions as described in the various embodiments herein. The processor 152 may be implemented by field programmable gate arrays (FPGAs), application specific integrated circuits (ASICs), systems on a chip (SOC), a general purpose computer, a central processing unit, a computer processor, a microprocessor, a graphics processing unit (GPU), a microcontroller, a state machine, programmable logic device, or combinations thereof, using any combination of hardware, software, firmware, hard-wired logic circuits, or combinations thereof. Additionally, any processing unit or processor herein may include multiple processors, parallel processors, or both. Multiple processors may be included in, or coupled to, a single device or multiple devices.

The term “processor” as used herein encompasses an electronic component able to execute a program or machine executable instruction. References to a computing device comprising “a processor” should be interpreted to include more than one processor or processing core, as in a multi-core processor. A processor may also refer to a collection of processors within a single computer system or distributed among multiple computer systems, such as in a cloud-based or other multi-site application. The term computing device should also be interpreted to include a collection or network of computing devices each including a processor or processors. Modules have software instructions to carry out the various functions using one or multiple processors that may be within the same computing device or which may be distributed across multiple computing devices.

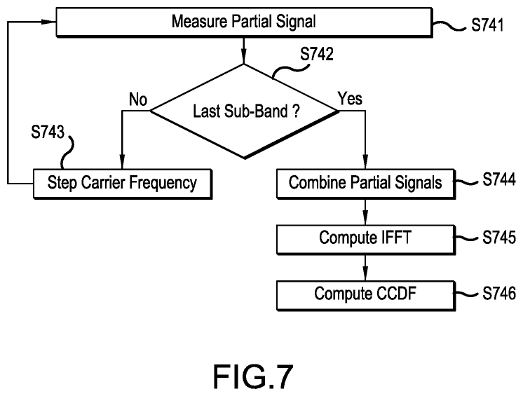

In one set of embodiments, the system 100 may comprise a network analyzer that performs a method described with respect to FIG. 7. The system 100 may execute instructions to step a carrier frequency over centers of multiple sub-bands so as to measure a corresponding partial signal in each narrower sub-band which is smaller than the modulation bandwidth, and then combines spectrums of the sub-bands to obtain a complete spectrum. The system 100 may also compute an inverse fast fourier transform to obtain a time domain signal from the complete spectrum, and then compute the CCDF from the time-domain signal based on upsampling the single measurement of the time-domain signal.

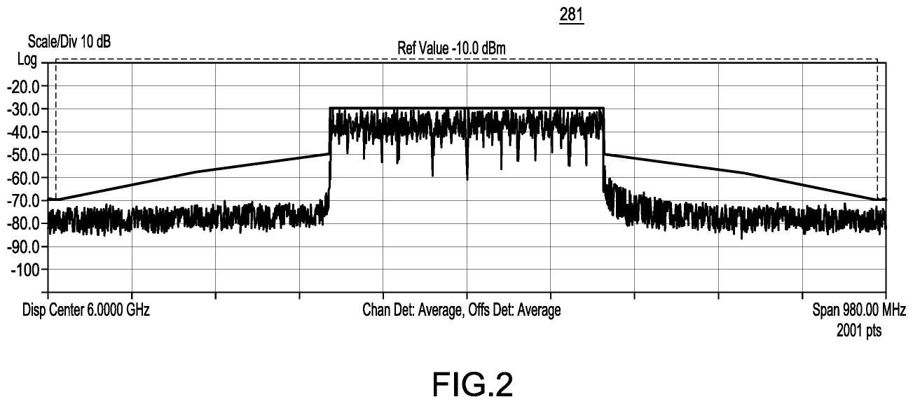

FIG. 2 illustrates a user interface of a spectrum analyzer showing signal measurements of a signal with a center frequency of 6 GHz in signal analysis for computing a complementary cumulative distribution function, in accordance with a representative embodiment.

A time-domain OFDM signal for the 320 MHz wide 802.11be signal may be displayed as instantaneous amplitude values over time, and a network analyzer may generate the frequency-domain representation shown on the user interface 281 in FIG. 2 with the spectrum that is 320 MHz wide. The 320 MHz portion of the signal is the elevated portion of the signal in the center in FIG. 2, with a ramp up in the beginning and a ramp down at the end.

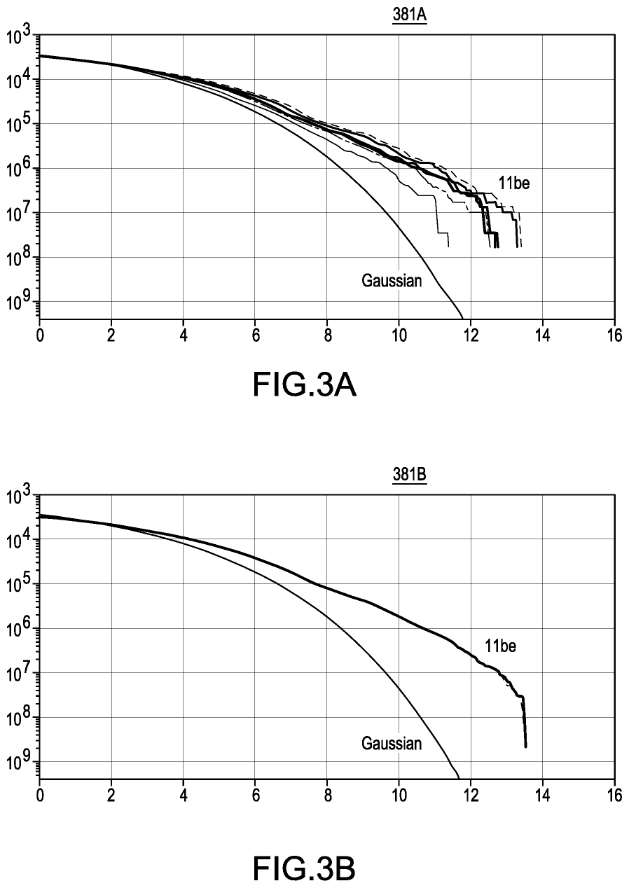

FIG. 3 illustrates a user interface showing varied results for a 400 MHz sampling rate without upsampling and consistent results for the 400 MHz sampling rate with 8 times upsampling, in accordance with a representative embodiment.

In FIG. 3, both the user interface 381A and the user interface 381B show CCDF curves with a normalized amplitude of the OFDM signal on the X-axis, and the probability of the OFDM signal being above the value of the X-axis on the Y-axis.

In FIG. 3, the user interface 381A in the upper panel illustrates variations in a bunched group of CCDF curves labelled 11be for multiple measurements of the OFDM signal in FIG. 2 with a 400 MHz sampling rate. The CCDF curves on the user interface 381A are for data that is not upsampled, and reflect a sampling rate of 1.25 times the Nyquist rate for 320 MHz. The sampling rate of 1.25 times the Nyquist rate may be the minimal sampling rate setting available on some network analyzers. The trace labeled Gaussian on the user interface 381A shows the result of increasing the bandwidth excessively for the same OFDM signal, as the result is effectively Gaussian noise.

The user interface 381B in the lower panel illustrates CCDF curves labelled 11be for multiple measurements of the OFDM signal in FIG. 2 with an 8-times digital upsampling of the underlying sampling rate of 1.25 times the Nyquist rate for 320 MHz. That is, the CCDF curves on the user interface 381B are for data that is upsampled at 8-times the underlying sampling rate of 1.25 times the Nyquist rate for 320 MHz. As shown, the diverging traces on the user interface 381A are replaced with essentially identical traces on the user interface 381B, and this is due to the digital upsampling of the underlying sampling rate of 1.25 times the Nyquist rate.

In FIG. 3, each trace of the bunched group on the user interface 381A is a different CCDF, but if they were averaged it would be close to the true CCDF as shown on the user interface 381B. That is, on the user interface 381B, CCDF variation is significantly reduced for the 802.11be CCDF over measurements with 8 times upsampling to obtain a 10 times Nyquist sampling rate.

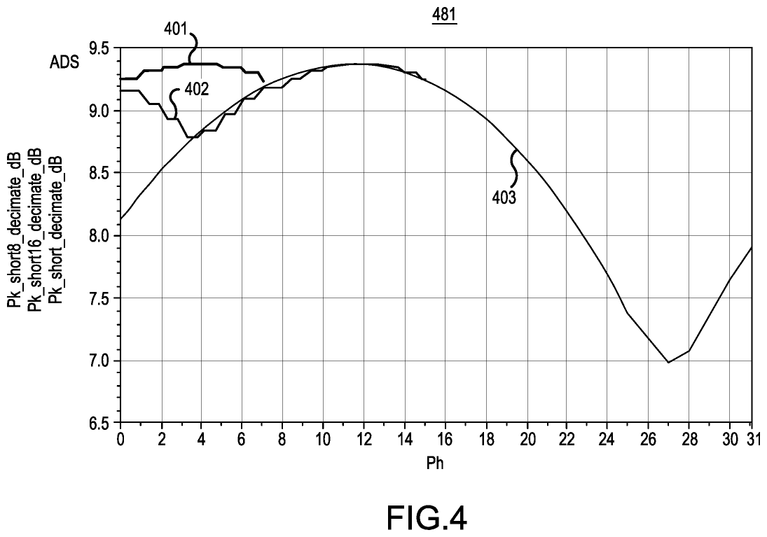

FIG. 4 illustrates a user interface showing variations of peak-to-average power ratio with sampling rate, over sampling delay between the source signal DAC clock and the measurement instrument's ADC clock, in accordance with a representative embodiment.

The simulated peak to average power ratio (PAPR) of a segment of a 20 MHz 11n OFDM signal versus the upsampled rate is shown in FIG. 4. In FIG. 4, the smoothest trace that is illustrated from the left side to the right side is sampled at 1 times the Nyquist sampling rate. The ragged middle trace immediately above the smoothest trace on the left side is sampled at 2 times the Nyquist sampling rate. The ragged highest trace on the left side is sampled at 4 times the Nyquist sampling rate.

In embodiments based on the teachings herein, a signal either at radio frequency or at a downconverted intermediate frequency may be initially digitized at a sampling rate higher than the 1.25× Nyquist sampling rate and bandpass filtered to remove out-of-band noise that will otherwise distort the CCDF of the signal. The digitizing may be performed by the A/D 108 in FIG. 1 and the bandpass filtering may be performed by digital down conversion at the controller 150 followed by low-pass filtering using, for example, an equi-ripple linear phase FIR filter with small pass-band ripple. Depending on the original sampling rate, the signal may be upsampled by 4 times or 8 times to obtain from 5 times to 10 times or higher than the Nyquist sampling rate for the CCDF measurement to be accurate. Notably, an equi-ripple linear phase FIR filter with small pass-band ripple does not change the upsampled peak-to-average ratio of the signal and doesn't have an impact on the true CCDF of the upsampled signal. Its purpose to to remove out-of-band noise. In one embodiment, the upsampling, interpolation and filtering can be accomplished by a single upsampling interpolation filter known in prior art. Moreover, the present teachings contemplate the hardware or software, or both, can be distributed or centralized.

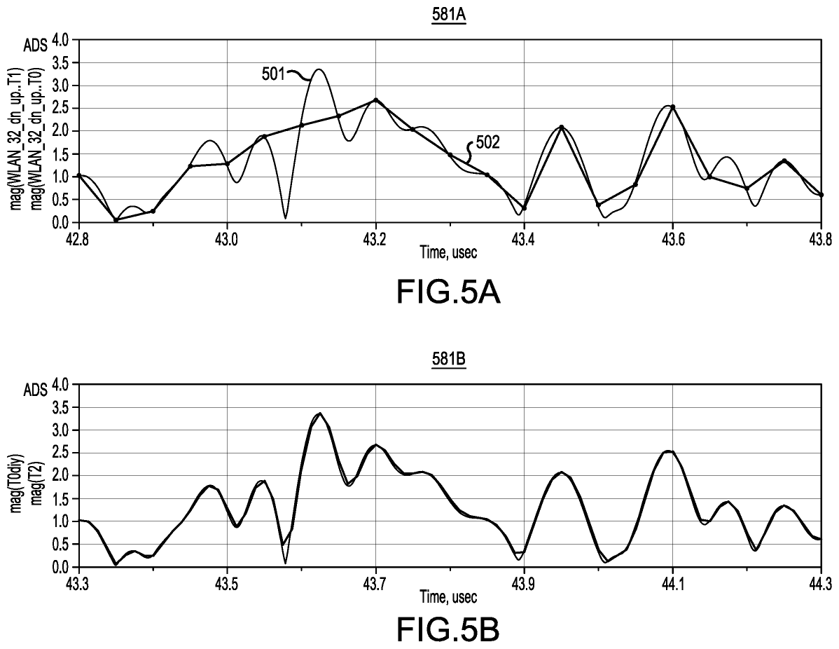

FIG. 5 illustrates a user interface showing effects of upsampling, in accordance with a representative embodiment.

In FIG. 5, the upper panel includes a first trace 501 that shows a signal sampled at a high rate much higher than the modulation bandwidth. The second trace 502 is sampled at a low rate and misses the peak of the waveform. The lower panel shows the result of upsampling by 4 times, so that the peaks from the second trace 502 in the upper panel are captured and the waveforms for the first trace 501 and the second trace 502 are substantially identical such that they are not labelled in the lower panel.

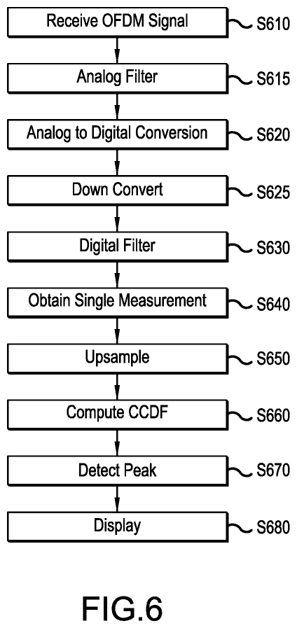

FIG. 6 illustrates a method for signal analysis for computing a complementary cumulative distribution function, in accordance with a representative embodiment.

At S610, an OFDM signal is received. For the purposes of the method in FIG. 6, the OFDM signal received at S610 may be a continuous signal that is captured via sampling beginning at a first point in time and ending at a second point in time. The OFDM signal may be received by sampling by samplers/sampling circuits (not shown) of the system 100 in FIG. 1, and provided for downconversion to the mixer 104.

At S615, an analog filter is applied to the received OFDM signal. For example, the analog filter 106 in FIG. 1 may be applied to the frequency downconverted intermediate radio frequency signal 133 from the mixer 104. The filtering at S615 may be with a first filtering bandwidth larger than a modulation bandwidth of the OFDM signal, and results in a filtered analog signal. The filtering at S615 may be with a bandwidth slightly larger than the modulation bandwidth in order to reject the out of band noise and prevent aliasing at the input of the A/D 108.

At S620, the filtered OFDM signal is subjected to analog-to-digital conversion. For example, the filtered analog input 135 which is filtered by the analog filter 106 in FIG. 1 may be provided to the A/D 108.

At S625, the digitized OFDM signal is digitally downconverted. For example, the controller 150 may digitally downconvert the digitized signal from the A/D 108.

At S630, a digital filter is applied to the down converted OFDM signal. For example, either the controller 150 or a separate component such as an application-specific integrated circuit performs digital filtering. After digitization by the A/D 108 at a sampling rate larger than 2 times the analog filter bandwidth to meet Nyquist criterion of the noise bandwidth, narrower digital filtering is performed at S630 with a bandwidth slightly larger than the modulation bandwidth to remove out-of-band noise from influencing the CCDF. As an example of S630, the controller 150 or a separate component in FIG. 1 may be configured to filter the digitization with a second filtering bandwidth larger than the modulation bandwidth and smaller than the first filtering bandwidth used at S615. The filtering by the controller 150 or the separate component is performed before upsampling the single measurement at the multiple of five (5) times or higher of the Nyquist sampling rate at S650. As an example, One or more of the interfaces provided by the system 100 in FIG. 1 may be configured to accept a selection of the multiple used to upsample the single measurement from a plurality of multiples. For example, the display 180 may display a set of potential multiples and a mouse or keyboard may be configured to accept a selection of the multiple used to upsample the single measurement from the plurality of multiples.

At S640, a single measurement of the digitally filtered OFDM signal is obtained. For example, the controller 150 may obtain a data set from the A/D 108 that begins with data corresponding to the beginning of the digitally filtered OFDM signal and that ends with data corresponding to the end of the digitally filtered OFDM signal.

At S650, the single measurement of the OFDM signal is upsampled. The upsampling is performed to effectively increase the sample size to capture samples which otherwise have very low probability of being captured. The data set from the A/D 108 may represent a sequence of samples of the OFDM signal received at S610. Upsampling performed on the sequence of samples of the digitally filtered OFDM signal may be performed at an upsampling rate, and provides additional zero values to the samples per period of the waveform. The upsampling may be at a multiple of five (5) times or higher of a Nyquist sampling rate. The upsampling may produce an approximation of the sequence of samples that would have been obtained by sampling the OFDM signal at a higher rate. Upsampling operations such as this may be referred to as “zero insertion.” As an example, the multiple may comprise five (5) times the Nyquist sampling rate, and may be obtained by upsampling at a multiple of 4 times an OFDM signal sampled originally at 1.25 times the Nyquist rate. As another example, the multiple may comprise ten (10) times the Nyquist sampling rate, and may be obtained by upsampling at 8 times an OFDM signal sampled originally at 1.25 times the Nyquist rate.

After upsampling at S650, a denser distribution of the sampling points over time is present in the captured waveform, and this results in an improved probability of capturing all the peaks from the sampled OFDM signal.

At S660, the CCDF of the upsampled single measurement is computed. For example, the CCDF of the upsampled single measurement may be computed by the controller 150 for a visualization requested by an operator of the system 100.

At S670, a peak in the CCDF of the upsampled single measurement is detected. For example, one or more peaks in the CCDF may be detected as in the bottom panel of the user interface 581 in FIG. 5

At S680, the CCDF of the upsampled single measurement including the detected peak is displayed. The CCDF curve displayed at S680 represents the modulated waveform of the OFDM signal received at S610. The CCDF curve is displayable based on computing the complementary cumulative distribution function of the modulated waveform of the OFDM signal received at S610.

Using the method of FIG. 6, CCDF of a modulated waveform may be accurately computed in real-time using only a single measurement. In some embodiments, the process of FIG. 6 may be repeated, such as several times, to confirm accuracy or even marginally improve accuracy of the least accurate measurement(s) by averaging with more accurate measurement(s).

FIG. 7 illustrates another method for signal analysis for computing a complementary cumulative distribution function, in accordance with a representative embodiment.

At S741, a partial signal is measured. The measurement at S741 may be the first measurement for a continuous signal sampled by the system 100 in FIG. 1.

At S742, a determination is made as to whether the sub-band for the partial signal measured at S741 is the last sub-band to be measured.

If the sub-band for the partial signal measured at S741 is not the last sub-band to be measured (S742=No), at S743 the carrier frequency may be stepped at S743 and the next partial signal for the next sub-band is measured at S741.

If the sub-band for the partial signal measured at S741 is the last sub-band to be measured (S742=Yes), at S744 the partial signals measured at S741 for the continuous signal may be combined at S744.

At S745, the inverse fast fourier transform (IFFT) for the combined partial signals is computed so as to produce a waveform of the combined partial signals in the time-domain. The IFFT may be computed by the controller 150 in FIG. 1.

At S750, upsampling is performed on the combined partial signals.

At S760, the CCDF is computed. For example, the CCDF of the combined partial signals may be computed by the controller 150 for display on the display 180 in FIG. 1.

As set forth above with respect the method of FIG. 7, the system 100 may execute instructions to step a carrier frequency. The system 100 may be a network analyzer that steps a carrier frequency over centers of multiple sub-bands so as to measure a corresponding partial signal in each narrower sub-band which is smaller than the modulation bandwidth. At S744 the system 100 combines spectrums of the sub-bands to obtain a complete spectrum; and at S745 the system 100 computes an inverse fast fourier transform to obtain a time domain signal from the complete spectrum. The CCDF computed at S746 is computed from the time-domain signal based on upsampling the single measurement of the time-domain signal at S745.

The method from S741 to S745 may be performed at or after S640 in FIG. 6, so that S750 and S760 are performed in the same manner as S650 and S660 in FIG. 6. FIG. 7 may be performed as a specific embodiment of obtaining a single measurement of a signal at S640 in FIG. 6. The carrier phase of a signal may be swept using the method of FIG. 7 to improve the phase randomization for enhancing CCDF accuracy using fewer repetitions. The method of FIG. 7 demonstrates an example of such sweeping. As an example, a network analyzer such as the system 100 in FIG. 1 may use sub-bands of 20 MHz or smaller with a 40 MHz A/D. Another network analyzer may have an A/D with a higher sampling rate, such that the use of sub-bands as in the method of FIG. 7 is not particularly required.

In an embodiment, dedicated hardware implementations, such as application-specific integrated circuits (ASICs), field programmable gate arrays (FPGAs), programmable logic arrays and other hardware components, are constructed to implement one or more of the methods described herein. One or more embodiments described herein may implement functions using two or more specific interconnected hardware modules or devices with related control and data signals that can be communicated between and through the modules. Accordingly, the present disclosure encompasses software, firmware, and hardware implementations. Nothing in the present application should be interpreted as being implemented or implementable solely with software and not hardware such as a tangible non-transitory processor and/or memory.

In accordance with various embodiments of the present disclosure, the methods described herein may be implemented using a hardware computer system that executes software programs. Further, in an exemplary, non-limited embodiment, implementations can include distributed processing, component/object distributed processing, and parallel processing. Virtual computer system processing may implement one or more of the methods or functionalities as described herein, and a processor described herein may be used to support a virtual processing environment.

Accordingly, signal analysis for computing a complementary cumulative distribution function enables accurate measurement of the CCDF of an undersampled waveform using a single measurement instead of taking the average of multiple CCDF measurements or computing CCDF over multiple waveforms that are concatenated. In addition to saving time, accuracy of CCDF measurements is improved using the teachings herein. The teachings herein are applicable to CCDF computations of compact test signals (CTS) used in network analyzers such as the modulation distortion measurement class of the PNA-X network analyzer (PNAX). Network analyzers that tend to under sample high-frequency signals may improve the accuracy of CCDF computations using the teachings herein.

Although signal analysis for computing a complementary cumulative distribution function has been described with reference to several exemplary embodiments, it is understood that the words that have been used are words of description and illustration, rather than words of limitation. Changes may be made within the purview of the appended claims, as presently stated and as amended, without departing from the scope and spirit of signal analysis for computing a complementary cumulative distribution function in its aspects. Although signal analysis for computing a complementary cumulative distribution function has been described with reference to particular means, materials and embodiments, signal analysis for computing a complementary cumulative distribution function is not intended to be limited to the particulars disclosed; rather signal analysis for computing a complementary cumulative distribution function extends to all functionally equivalent structures, methods, and uses such as are within the scope of the appended claims. Finally, while an OFDM signal has been used as an example this is not intended to be limiting of the application of the present teachings. More generally, the present teachings contemplate application to many arbitrary waveforms for which the CCDF needs to be measured.

The illustrations of the embodiments described herein are intended to provide a general understanding of the structure of the various embodiments. The illustrations are not intended to serve as a complete description of all of the elements and features of the disclosure described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is provided to comply with 37 C.F.R. § 1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The preceding description of the disclosed embodiments is provided to enable any person skilled in the art to practice the concepts described in the present disclosure. As such, the above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents and shall not be restricted or limited by the foregoing detailed description.

I claim:

1. A signal analysis system, comprising:
a memory that stores instructions; and
a processor that executes the instructions, wherein, when executed by the processor, the instructions cause the signal analysis system to: filter an orthogonal frequency-division multiplexed signal with a first filtering bandwidth larger than a modulation bandwidth of the orthogonal frequency-division multiplexed signal to produce a filtered analog signal; digitize the filtered analog signal to obtain a digitization of the filtered analog signal; obtain a single measurement of a modulated waveform from the digitization; upsample the single measurement at a multiple of five (5) times or higher of a Nyquist sampling rate; and compute a complementary cumulative distribution function (CCDF) of the modulated waveform of the orthogonal frequency-division multiplexed signal based on upsampling the single measurement.

2. The signal analysis system of claim 1, wherein the multiple comprises ten (10) times the Nyquist sampling rate.

3. The signal analysis system of claim 1, further comprising:
a display, wherein, when executed by the processor, the instructions further cause the signal analysis system to:
detect a peak in the modulated waveform; and
display the modulated waveform on the display including the peak based on computing the complementary cumulative distribution function of the modulated waveform.

4. The signal analysis system of claim 1, wherein, when executed by the processor, the instructions further cause the signal analysis system to:
filter the digitization with a second filtering bandwidth larger than the modulation bandwidth and smaller than the first filtering bandwidth before upsampling the single measurement at the multiple of five (5) times or higher of the Nyquist sampling rate, wherein digitizing the filtered analog signal is performed at a sampling rate higher than one (1) times the Nyquist sampling rate.

5. The signal analysis system of claim 4, further comprising:
a low-pass filter, wherein, when executed by the processor, the instructions further cause the signal analysis system to:
digitally downconvert the digitization; and
apply the digitization to the low-pass filter either before or after upsampling the single measurement.

6. The signal analysis system of claim 5, wherein the low-pass filter comprises a linear phase FIR filter.

7. The signal analysis system of claim 1, wherein, when executed by the processor, the instructions further cause the signal analysis system to:
accept a selection of the multiple used to upsample the single measurement from a plurality of multiples.

8. The signal analysis system of claim 1, wherein the signal analysis system comprises a network analyzer, or a spectrum analyzer or a signal analyzer.

9. The signal analysis system of claim 8, wherein, when executed by the processor, the instructions further cause the signal analysis system to:
step a carrier frequency of the network analyzer over centers of multiple sub-bands and measure a corresponding partial signal in each narrower sub-band which is smaller than the modulation bandwidth;
combine spectrums of the sub-bands to obtain a complete spectrum;
compute an inverse fast fourier transform to obtain a time domain signal from the complete spectrum; and
compute the complementary cumulative distribution function from the time domain signal based on upsampling the single measurement of the time domain signal.

10. The signal analysis system of claim 1, wherein the Nyquist sampling rate for the orthogonal frequency-division multiplexed signal before the upsampling is 1.25, and the upsampling is at a multiple of at least 4 times the Nyquist sampling rate.

11. A tangible non-transitory computer readable storage medium that stores a computer program, wherein the computer program, when executed by a processor, causes a system to:
filter an orthogonal frequency-division multiplexed signal with a first filtering bandwidth larger than a modulation bandwidth of the orthogonal frequency-division multiplexed signal to produce a filtered analog signal;
digitize the filtered analog signal to obtain a digitization of the filtered analog signal;
obtain a single measurement of a modulated waveform from the digitization;
upsample the single measurement at a multiple of five (5) times or higher of a Nyquist sampling rate; and
compute a complementary cumulative distribution function (CCDF) of the modulated waveform of the orthogonal frequency-division multiplexed signal based on upsampling the single measurement.

12. The tangible non-transitory computer readable storage medium of claim 11, wherein the multiple comprises ten (10) times the Nyquist sampling rate.

13. The tangible non-transitory computer readable storage medium of claim 11, wherein the computer program, when executed by a processor, causes the system to:
detect a peak in the modulated waveform; and
display a modulated waveform including the peak based on computing the complementary cumulative distribution function of the modulated waveform.

14. The tangible non-transitory computer readable storage medium of claim 11, wherein the computer program, when executed by a processor, causes the system to:
filter the digitization with a second filtering bandwidth larger than the modulation bandwidth and smaller than the first filtering bandwidth before upsampling the single measurement at a multiple of five (5) times or higher of the Nyquist sampling rate, wherein digitizing the filtered analog signal is performed at a sampling rate higher than one (1) times the Nyquist sampling rate.

15. The tangible non-transitory computer readable storage medium of claim 14, wherein the computer program, when executed by a processor, causes the system to:
digitally downconvert the digitization; and
apply the digitization to a low-pass filter before upsampling the single measurement.

16. The tangible non-transitory computer readable storage medium of claim 15, wherein the low-pass filter comprises a linear phase FIR filter.

17. The tangible non-transitory computer readable storage medium of claim 11, wherein the computer program, when executed by a processor, causes the system to:
accept a selection of the multiple used to upsample the single measurement from a plurality of multiples.

18. The tangible non-transitory computer readable storage medium of claim 11, wherein the system comprises a network analyzer.

19. The tangible non-transitory computer readable storage medium of claim 18, wherein the computer program, when executed by a processor, causes the system to:
step a carrier frequency of the network analyzer over centers of multiple sub-bands and measure a corresponding partial signal in each narrower sub-band which is smaller than the modulation bandwidth;
combine spectrums of the sub-bands to obtain a complete spectrum;
compute an inverse fast fourier transform to obtain a time domain signal from the complete spectrum; and
compute the complementary cumulative distribution function from the time domain signal based on upsampling the single measurement of the time domain signal.

20. The tangible non-transitory computer readable storage medium of claim 11, wherein the Nyquist sampling rate for the orthogonal frequency-division multiplexed signal before the upsampling is 1.25, and the upsampling is at a multiple of at least 4 times the Nyquist sampling rate.
